(19) United States
(12) Patent Application Publication
(10) Pub. No.: US 2010/0001379 A1
(43) Pub. Date: Jan. 7, 2010

(54) Multi-chip package (MCP) having three dimensional mesh-based power distribution network, and power distribution method of the MCP

(76) Inventors: Hoon Lee, Seoul (KR); Kang-wook Lee, Suwon-si (KR); Uk-song Kang, Seongnam-si (KR)

Correspondence Address: LEE & MORSE, P.C., 3141 FAIRVIEW PARK DRIVE, SUITE 500, FALLS CHURCH, VA, 22042, US

(21) Appl. No.: 12/458,124

(22) Filed: Jul. 1, 2009

(30) Foreign Application Priority Data
Jul. 2, 2008 (KR) 10-2008-0063967

(51) Int. Cl. H01L 29/40; H01L 21/00; H01L 21/44

(52) U.S. Cl. 257/621; 438/107; 438/667; 257/E29.111; 257/E21.001; 257/E21.476

(57) ABSTRACT

A MCP includes a plurality of semiconductor memory devices, the plurality of semiconductor memory devices being stacked to define a three-dimensional (3D) structure, and a mesh structure, the mesh structure interconnecting the plurality of semiconductor memory devices to define a 3D mesh-based power distribution network.

### BACKGROUND

1. Field

Example embodiments relate to a power distribution network of a semiconductor device, and more particularly, to a power distribution network of a multi-chip package (MCP) and a power distribution method of the MCP.

2. Description of the Related Art

Due to an increase of capacity and switching speed of a semiconductor device, i.e., operating speed of the semiconductor device, an amount of current flowing via a power distribution network of the semiconductor device may increase. As a result of this current increase, a voltage drop in the power distribution network of the semiconductor device may increase, thereby causing problems. Further, a MCP, i.e., a structure including semiconductor memory devices stacked in a three-dimensional (3D) manner, may have even a larger capacity requiring high power, thereby causing a high voltage drop in a power distribution network of the MCP. The high voltage drop may reduce power stability in the MCP.

### SUMMARY

Embodiments are therefore directed to a power distribution network of a MCP and a power distribution method of the MCP, which substantially overcome one or more of the problems due to the limitations and disadvantages of the related art.

It is therefore a feature of an embodiment to provide a MCP with a power distribution network having reduced voltage drop and improved power stability.

It is therefore another feature of an embodiment to provide a power distribution method for a MCP exhibiting improved power delivery and stability.

At least one of the above and other features and advantages may be realized by providing a MCP, including a plurality of semiconductor memory devices stacked in a three-dimensional (3D) manner, wherein the plurality of semiconductor memory devices are interconnected in a form of a mesh so that a 3D mesh-based power distribution network is formed.

The TSVs may be interconnected in a form of mesh on each of the plurality of semiconductor memory devices so that a two dimensional (2D) mesh-based power distribution network is formed. The MCP may include a mesh structure having a plurality of TSVs arranged in a 3D structure, the TSVs interconnecting the plurality of semiconductor memory devices.

The TSVs may be formed not only in regions dividing banks of each of the plurality of semiconductor memory devices but also formed in the vicinity of a chip edge in each of the plurality of semiconductor memory devices. The TSVs may be formed only in the vicinity of a chip edge in each of the semiconductor memory devices. The TSVs may be formed between a chip edge and a scribe line of each of the plurality of semiconductor memory devices. The TSVs may be connected to a power pad via a redistributed power line on each of the plurality of semiconductor memory devices.

At least one of the above and other features and advantages may also be realized by providing a MCP, including a plurality of semiconductor memory devices, the plurality of semiconductor memory devices being stacked to define a 3D structure, each of the plurality of semiconductor memory devices having a 2D mesh-based power distribution network, and a mesh structure, the mesh structure interconnecting the 2D mesh-based power distribution networks of the plurality of semiconductor memory devices three-dimensionally to define a 3D mesh-based power distribution network.

At least one of the above and other features and advantages may also be realized by providing a power distribution method of a MCP, the power distribution method including the operations of forming a 2D mesh-based power distribution network on each of a plurality of semiconductor memory devices, stacking the plurality of semiconductor memory devices, interconnecting the plurality of semiconductor memory devices by using TSVs, and forming a 3D mesh-based power distribution network, and distributing power via the 2D mesh-based power distribution network and the 3D mesh-based power distribution network.

### BRIEF DESCRIPTION OF THE DRAWINGS

The above and other features and advantages will become more apparent to those of ordinary skill in the art by describing in detail exemplary embodiments with reference to the attached drawings, in which:

FIG. 1 illustrates a MCP according to an example embodiment;

FIG. 2 illustrates a diagram of a semiconductor memory device in a MCP according to an example embodiment;

FIG. 3 illustrates a diagram of a semiconductor memory device in a MCP according to another example embodiment;

FIG. 4 illustrates a diagram of a semiconductor memory device in a MCP according to another example embodiment;

FIG. 5 illustrates a magnified view of a portion of the semiconductor memory device in FIG. 4;

FIG. 6 illustrates a diagram of a semiconductor memory device in a MCP according to another example embodiment;

FIG. 7 illustrates a cross-sectional view of the semiconductor memory device of FIG. 6 taken along line A-A′; and

FIG. 8 illustrates a flowchart of a power distribution method of a MCP according to an example embodiment.

### DETAILED DESCRIPTION OF THE INVENTION

Korean Patent Application No. 10-2008-0063967, filed on Jul. 2, 2008, in the Korean Intellectual Property Office, and entitled: “Multi-Chip Package (MCP) Having Three Dimensional Mesh-Based Power Distribution Network, and Power Distribution Method of the MCP,” is incorporated by reference herein in its entirety.

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the invention to those skilled in the art.

In the drawing figures, the dimensions of layers and regions may be exaggerated for clarity of illustration. It will also be understood that when a layer or element is referred to as being “on” another layer or substrate, it can be directly on the other layer or substrate, or intervening layers may also be present. In addition, it will also be understood that when a layer is referred to as being “between” two layers, it can be the only layer between the two layers, or one or more intervening layers may also be present. Like reference numerals refer to like elements throughout.

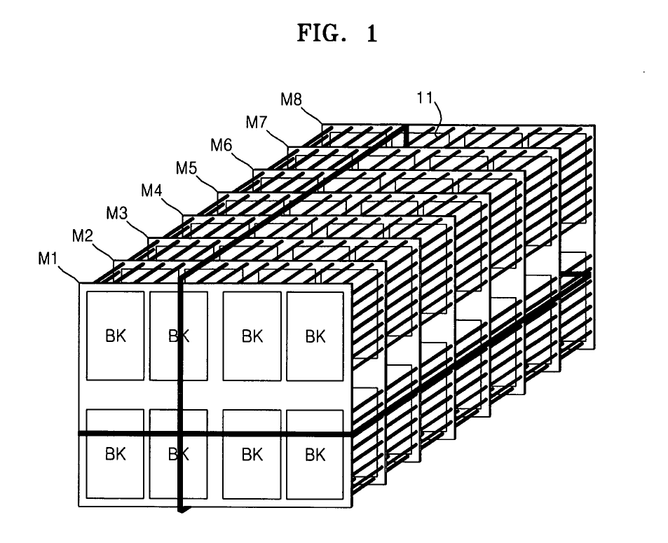

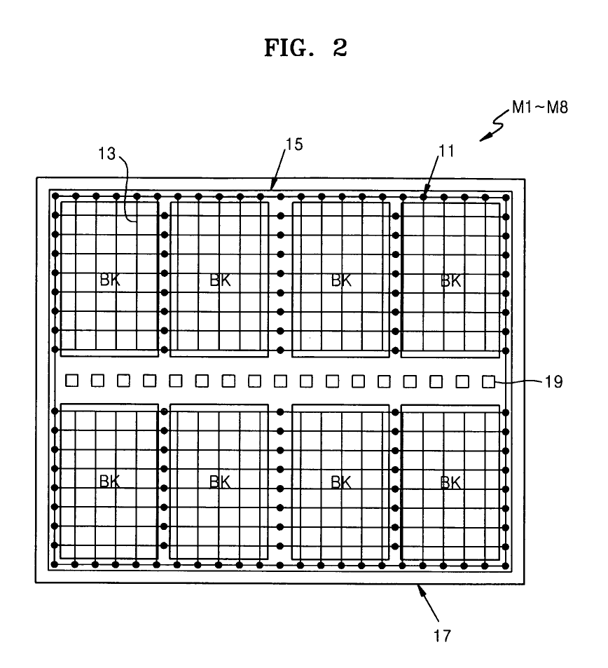

FIG. 1 illustrates a diagram of a MCP according to an embodiment of the inventive concept. FIG. 2 illustrates a diagram of a semiconductor memory device corresponding to one of a plurality of semiconductor memory devices M1 through M8 of the MCP in FIG. 1 according to an embodiment of the inventive concept.

Referring to FIG. 1, the MCP may include the plurality of semiconductor memory devices, e.g., semiconductor memory devices M1 through M8. The plurality of the semiconductor memory devices M1 through M8 may include a plurality of banks and may be stacked in a three-dimensional (3D) manner, e.g., sequentially one on another. The semiconductor memory devices M1 through M8 may be interconnected, e.g., using a plurality of Through Silicon Vias (TSVs) 11.

The plurality of TSVs 11 may be arranged in the MCP in a 3D mesh structure to interconnect the semiconductor memory devices M1 through M8, e.g., all the semiconductor memory devices M1 through M8. In other words, the semiconductor memory devices M1 through M8 may be three-dimensionally interconnected in a form of a mesh by using the TSVs 11, so that a 3D mesh-based power distribution network may be formed. For example, the plurality of TSVs 11 may extend along a first direction, and may be spaced apart from each other along a second direction and along a third direction to form the 3D mesh. In other words, one TSV 11 may extend along the first direction, and may be spaced apart from an adjacent TSV 11 along each of the second direction and the third direction. For example, the first, second, and third directions may be perpendicular to each other.

Also, referring to FIG. 2, the TSVs 11 of a single semiconductor memory device of the MCP may be interconnected in a form of a mesh by using a conductive material 13, e.g., a metal line, so that a two-dimensional (2D) mesh-based power distribution network may be formed, e.g., in each of the semiconductor memory devices M1 through M8. For example, a plurality of TSVs 11 in a single semiconductor memory device of the MCP may be spaced apart from each other along the second and third directions, and may be interconnected to each other via the conductive material 13. Arrangement and interconnection of the plurality of the semiconductor memory devices M1 through M8 with the 2D mesh-based power distribution network into the MCP may provide the 3D mesh-based power distribution network. Power may be distributed to the semiconductor memory devices M1 through M8 via the TSVs 11. The TSVs 11 may be formed of a conductive material, e.g., Cu, etc.

As illustrated in FIG. 2, a semiconductor memory device, e.g., each of the semiconductor memory devices M1 through M8, may include plurality of banks. (BKs) spaced apart from each other and arranged, e.g., in a matrix pattern, and a plurality of pads 19. For example, as illustrated in FIG. 2, the plurality of pads 19 may be arranged to be adjacent to each other along the second direction between two rows of BKs, e.g., the two rows of the BKs may be spaced apart from each other along the third direction. The TSVs 11 may be arranged in regions dividing the BKs of the semiconductor memory device and in the vicinity of a chip edge 15 of the semiconductor memory device including a scribe line 17 and the pads 19. The scribe line 17 may surround the chip edge 15. For example, the TSVs 11 may be arranged along the chip edge 15 of the semiconductor memory device, e.g., only in regions extending along and overlapping the BKs, and may be arranged between adjacent BKs, e.g., a predetermined number of TSVs 11 may be positioned between two BKs adjacent to each other along the second direction.

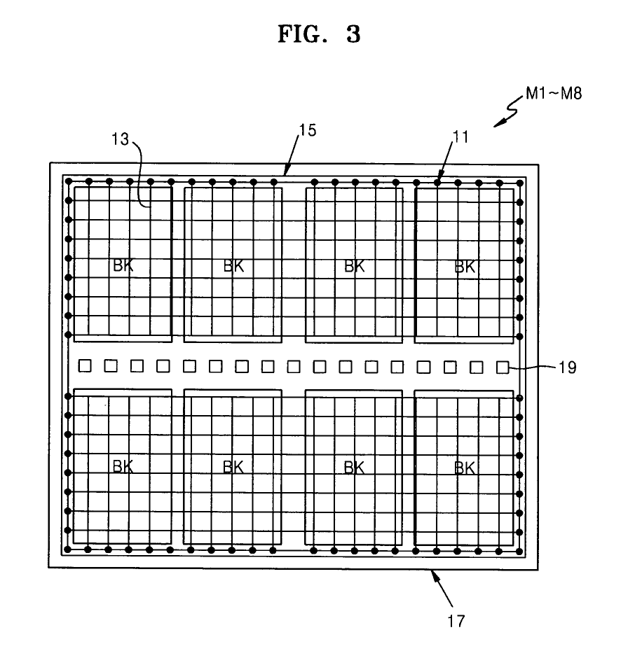

FIG. 3 illustrates a diagram of a semiconductor memory device corresponding to one of the plurality of semiconductor memory devices M1 through M8 of the MCP in FIG. 1 according to another example embodiment. As illustrated in FIG. 3, the TSVs 11 may be formed only in the vicinity of the chip edge 15 of the semiconductor memory device, i.e., the TSVs 11 may not be formed between adjacent BKs. For example, as illustrated in FIG. 3, the TSVs 11 may be arranged along portions of the chip edge 15 of the semiconductor memory device, e.g., to define a L-shape arrangement in each corner of the semiconductor memory device.

In this manner, when the TSVs 11 are formed in the vicinity of the chip edge 15, a chip size of the semiconductor memory device may be enlarged but a 3D mesh-based power distribution network may be realized with a MCP architecture to provide a stable power delivery to the MCP. Also, the TSVs 11 used to supplement power may be used as dummy TSVs for heat dissipation.

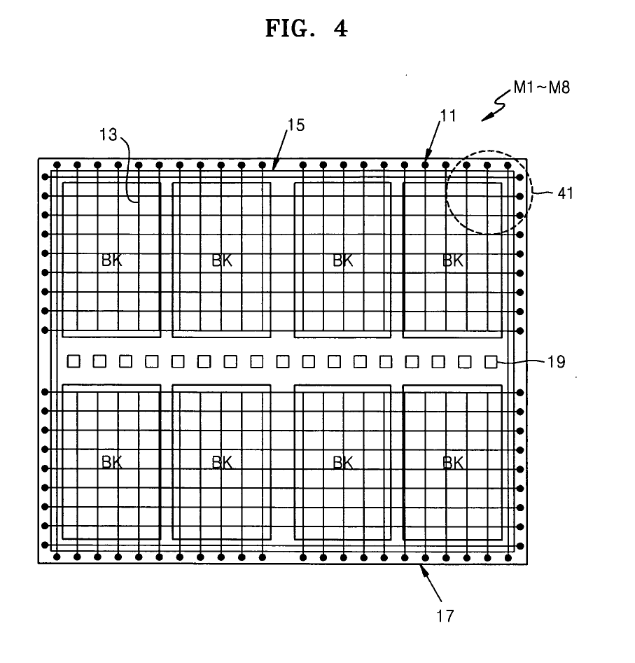

FIG. 4 illustrates a diagram of a semiconductor memory device corresponding to one of the plurality of semiconductor memory devices M1 through M8 of the MCP in FIG. 1 according to another example embodiment. As illustrated in FIG. 4, the TSVs 11 may be formed between the chip edge 15 and the scribe line 17 of the semiconductor memory device.

In general, a width between the chip edge 15 and the scribe line 17 may be about 45 μm, and a diameter of each TSV 11 may be about 15 μm. Thus, it may be possible to dispose the TSVs 11 between the chip edge 15 and the scribe line 17 of the semiconductor memory device.

Conventionally, a blade cutter may be used to cut a scribe line of a semiconductor memory device, so a gap having a width of about 45 μm may be formed between a chip edge and the scribe line. However, the wafer on which the semiconductor memory device according to example embodiments are to be formed may be processed via a thinning operation to facilitate stacking of the semiconductor memory devices M1 through M8 in the manner shown in FIG. 1. Accordingly, a laser cutter may be used to cut the scribe line 17 in consideration of the characteristics of the wafer. Use of the laser cutter for the scribe lines 17 when stacking semiconductor memory devices M1 through M8 in the MCP may reduce the cutting effect sufficiently so as to be ignored. In other words, a sufficient space between the scribe line 17 and the chip edge 15 may be left for disposing the TSVs 11 therebetween.

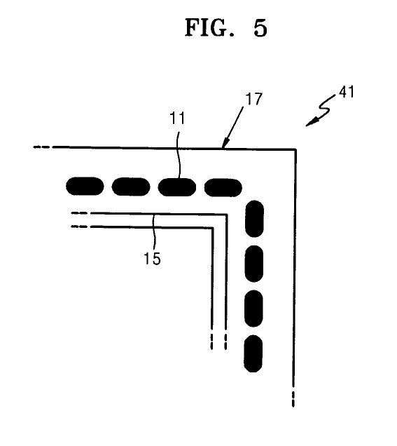

FIG. 5 illustrates a magnified drawing of a portion 41 of the semiconductor memory device in FIG. 4. In general, a guard-ring may be formed in the vicinity of the chip edge 15 so as to enhance reliability of the chip of the semiconductor memory device. In this regard, when the TSVs 11 according to example embodiments are disposed between the chip edge 15 and the scribe line 17 of the semiconductor memory device, the TSVs 11 may function as the guard-ring. Therefore, the reliability of the semiconductor memory devices may be highly enhanced and a 3D mesh-based power distribution network may be configured.

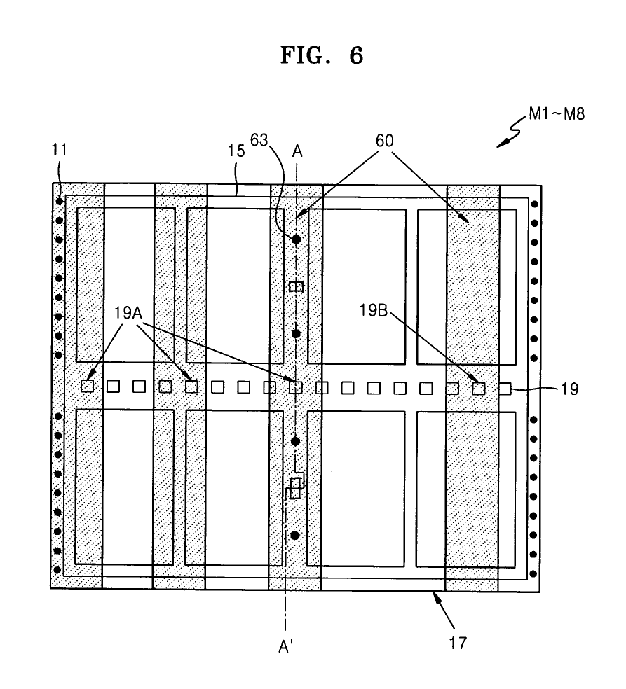

FIG. 6 illustrates a diagram of a semiconductor memory device corresponding to one of the plurality of semiconductor memory devices M1 through M8 of the MCP in FIG. 1 according to another example embodiment. In the semiconductor memory device illustrated in FIG. 6, the TSVs 11 may be connected to one of power pads 19A and power pads 19B via a redistributed power line 60 on the semiconductor memory device. For example, as illustrated in FIG. 6, the TSVs 11 may be positioned between the chip edge 15 and the scribe line 17 of the semiconductor memory device, and may be spaced apart from each other along the third direction. As further illustrated in FIG. 6, the redistributed power lines 60 may extend along the third direction, and may be spaced apart from each other along the second direction.

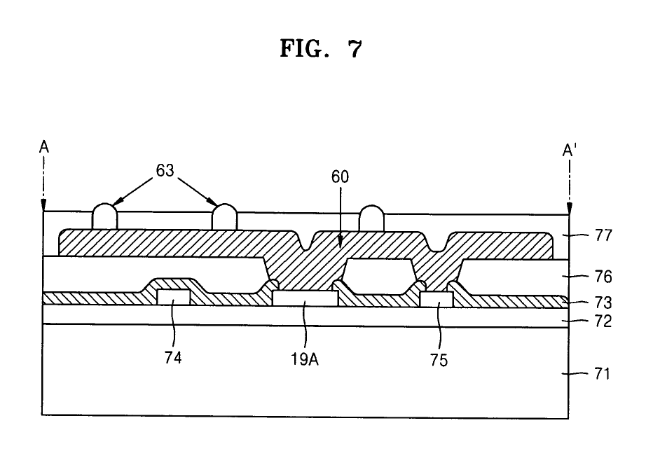

FIG. 7 illustrates a cross-sectional view of the semiconductor memory device of FIG. 6 along a line A-A′. Referring to FIG. 7, an insulating layer 72 and a passivation layer 73 may be formed on a substrate 70. Also, in FIG. 7, a signal line 74 and a power line 75 may be formed on the substrate 70, e.g., between the insulating layer 72 and the passivation layer 74. A power pad 19A may be formed on the substrate 70, e.g., between the signal line 74 and the power line 75. Also, as illustrated in FIG. 7, first and second dielectric layers 76 and 77 may be formed on the substrate 70, e.g., to cover the passivation layer 74. The redistributed power line 60 may be formed between the first and second dielectric lines 76 and 77. As further illustrated in FIG. 7, the redistributed power line 60 may be in contact with the power pad 19A. The TSVs (not shown) may be connected to the redistributed power line 60 via bumps 63.

As shown in FIG. 7, the redistributed power line 60 may be formed by using a metal line layer, e.g., in a back-end process. When the redistributed power line 60 is formed via the back-end process, the redistributed power line 60 may be formed to have a desired shape and a desired dimension with low costs.

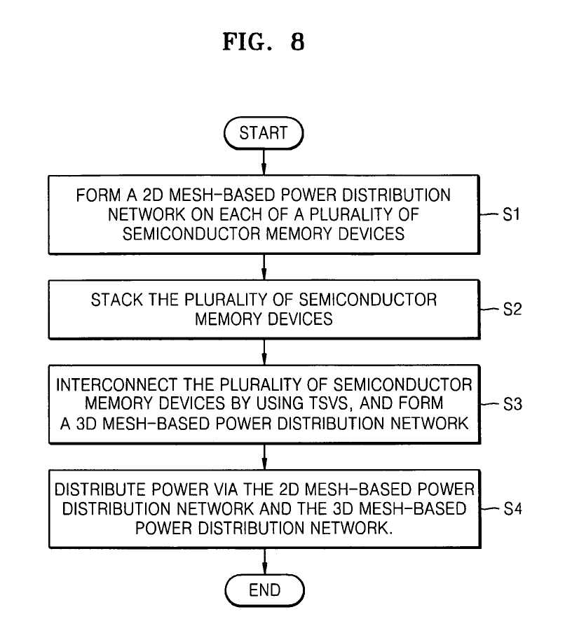

FIG. 8 illustrates a flowchart of a power distribution method of the MCP in FIG. 1 according to an example embodiment.

Referring to FIG. 8, the power distribution method of the MCP according to an example embodiment includes operations S1 through S4. First, a 2D mesh-based power distribution network in a form of a mesh may be formed on each of a plurality of semiconductor memory devices (operation S1). Then, the semiconductor memory devices individually having the 2D mesh-based power distribution network may be stacked (operation S2) to form the MCP. After that, the semiconductor memory devices may be three dimensionally interconnected in a form of a mesh by using TSVs, so that a 3D mesh-based power distribution network may be formed (operation S3). Then, power may be distributed via the 2D mesh-based power distribution network and the 3D mesh-based power distribution network (operation S4).

The TSVs may be interconnected in the form of a mesh on each of the semiconductor memory devices by using a conductive material, e.g., a metal line, so that the TSVs may form a 2D mesh-based power distribution network on each of the semiconductor memory devices. A plurality of semiconductor memory devices with 2D mesh-based power distribution network may be interconnected to each other via TSVs in a 3D mesh-based power distribution network to form a MCP.

Exemplary embodiments have been disclosed herein, and although specific terms are employed, they are used and are to be interpreted in a generic and descriptive sense only and not for purpose of limitation. Accordingly, it will be understood by those of ordinary skill in the art that various changes in form and details may be made without departing from the spirit and scope of the present invention as set forth in the following claims.

What is claimed is:

1. A multi-chip package (MCP), comprising:
a plurality of semiconductor memory devices, the plurality of semiconductor memory devices being stacked to define a three-dimensional (3D) structure; and
a mesh structure, the mesh structure interconnecting the plurality of semiconductor memory devices to define a 3D mesh-based power distribution network.

2. The MCP as claimed in claim 1, wherein the mesh structure includes a plurality of Through Silicon Vias (TSVs).

3. The MCP as claimed in claim 2, wherein power is distributed via the TSVs.

4. The MCP as claimed in claim 2, wherein the TSVs are arranged to interconnect with each other in each of the semiconductor memory devices, the TSVs being arranged in a two-dimensional (2D) structure in each of the semiconductor memory devices to define a 2D mesh-based power distribution network in each of the semiconductor memory devices.

5. The MCP as claimed in claim 4, wherein the TSVs are arranged to interconnect the plurality of semiconductor memory devices, the TSVs in each of the semiconductor memory devices being connected to at least one adjacent semiconductor memory device to define a 3D structure for the 3D mesh-based power distribution network.

6. The MCP as claimed in claim 1, wherein the mesh structure includes a plurality of TSVs arranged in a 3D structure, the TSVs interconnecting the plurality of semiconductor memory devices.

7. The MCP as claimed in claim 6, wherein the TSVs are positioned in regions of chip edges in each of the semiconductor memory devices.

8. The MCP as claimed in claim 7, wherein the TSVs are positioned only along chip edges in each of the semiconductor memory devices.

9. The MCP as claimed in claim 7, wherein the TSVs are further positioned between adjacent banks in each of the semiconductor memory devices.

10. The MCP as claimed in claim 7, wherein the TSVs are positioned between the chip edge and a scribe line of each of the plurality of semiconductor memory devices.

11. The MCP as claimed in claim 7, wherein the TSVs are connected to a power pad via a redistributed power line in each of the plurality of semiconductor memory devices.

12. A multi-chip package (MCP), comprising:
a plurality of semiconductor memory devices, the plurality of semiconductor memory devices being stacked to define a 3D structure, each of the plurality of semiconductor memory devices having a 2D mesh-based power distribution network; and
a mesh structure, the mesh structure interconnecting the 2D mesh-based power distribution networks of the plurality of semiconductor memory devices three-dimensionally to define a 3D mesh-based power distribution network.

13. The MCP as claimed in claim 12, wherein the plurality of semiconductor memory devices are interconnected by using Through Silicon Vias (TSVs), power being distributed via the TSVs.

14. The MCP as claimed in claim 13, wherein the TSVs are interconnected in a form of a 2D mesh on each of the plurality of semiconductor memory devices to define the 2D mesh-based power distribution network.

15. The MCP as claimed in claim 13, wherein the TSVs are interconnected in a form of a 3D mesh to interconnect the plurality of semiconductor memory devices three dimensionally to define the 3D mesh-based power distribution network.

16. The MCP as claimed in claim 13, wherein the TSVs are positioned between banks of each of the plurality of semiconductor memory devices and along a chip edge in each of the plurality of semiconductor memory devices.

17. The MCP as claimed in claim 13, wherein the TSVs are positioned only along a chip edge in each of the semiconductor memory devices.

18. The MCP as claimed in claim 13, wherein the TSVs are positioned between a chip edge and a scribe line of each of the plurality of semiconductor memory devices.

19. A power distribution method of a multi-chip package (MCP), comprising:
forming a 2D mesh-based power distribution network in each of a plurality of semiconductor memory devices;
stacking the plurality of semiconductor memory devices in a 3D structure;
interconnecting the 2D mesh-based power distribution networks of the plurality of semiconductor memory devices three-dimensionally via a mesh structure to define a 3D mesh-based power distribution network; and
distributing power via the 2D mesh-based power distribution network and the 3D mesh-based power distribution network.

20. The power distribution method as claimed in claim 19, wherein interconnecting the semiconductor memory devices via the mesh structure includes:
arranging Through Silicon Vias (TSVs) in a 2D structure in each semiconductor memory device to define the 2D mesh-based power distribution network; and
interconnecting the TSVs of the plurality of the semiconductor memory devices in a 3D structure to define the 3D mesh-based power distribution network.
